(19) United States
(12) Patent Application Publication
(10) Pub. No.: US 2006/0223332 A1
(43) Pub. Date: Oct. 5, 2006

(54) Method of manufacturing semiconductor device

(75) Inventors: Young Geun Jang, Seoul (KR); Sang Deok Kim, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Kyoungki-do (KR)

(21) Appl. No.: 11/299,079

(22) Filed: Dec. 8, 2005

(30) Foreign Application Priority Data
Mar. 30, 2005 (KR) 2005-26528

(51) Int. Cl. H01L 21/31; H01L 21/469

(52) U.S. Cl. 438/758

(57) ABSTRACT

A method of manufacturing semiconductor devices includes forming an interlayer insulation film over a semiconductor substrate, the substrate having a first gate structure for a memory cell and a second gate structure for a control transistor, the interlayer insulation film overlying the first and second gate structures; annealing the interlayer insulation film; etching the interlayer insulation film to form a contact hole to expose a conductive region associated with the second gate structure; and forming an oxide film over a surface of the interlayer insulation film and over a surface of the contact hole using ozone.

### BACKGROUND OF THE INVENTION

The present invention relates to a method of manufacturing semiconductor devices, and more particularly, to a method of manufacturing semiconductor devices, in which an interlayer insulation film is etched to form a contact.

As the level of integration of semiconductor devices is increased, an interlayer insulation film for insulating a lower structure, e.g., a lower cell or a transistor, and an upper wiring structure is formed using O₃-TEOS having a better gap-fill characteristic than that of an existing Chemical Vapor Deposition (CVD) method. The interlayer insulation film formed of O₃-TEOS is densified by a subsequent annealing process.

The densification by the anneal process, however, becomes less toward the bottom of the interlayer insulation film. Therefore, in the process of etching the interlayer insulation film to form the contact, a portion of the interlayer insulation film, which has not been densified, at the bottom of the interlayer insulation film is exposed and is therefore lost during a cleaning process to remove the etch remnants, resulting in a contact hole whose lower side is wider than its upper side is formed. A subsequent plug material may not completely fill into the contact hole.

### BRIEF SUMMARY OF THE INVENTION

An emobodiment of the present invention provides a method of manufacturing semiconductor devices, in which the bottom of an interlayer insulation formed of O₃-TEOS can be prevented from being removed during a cleaning process when the interlayer insulation film is etched to form a contact.

A method of manufacturing semiconductor devices according to the present invention includes the steps of forming an interlayer insulation film using O₃-TEOS on a semiconductor substrate having a predetermined structure formed therein, performing an anneal process to densify the interlayer insulation film, etching a predetermined region of the interlayer insulation film to form a contact through which a predetermined region of the semiconductor substrate is exposed, and forming an oxide film on a surface of the interlayer insulation film performing a surface process using ozone.

A method of manufacturing semiconductor devices according to the present invention includes the steps of forming a first interlayer insulation film using O₃-TEOS on a semiconductor substrate having a predetermined structure formed therein, performing an anneal process to densify the first interlayer insulation film, forming a second interlayer insulation film on the first interlayer insulation film, etching predetermined regions of the first and second interlayer insulation films to form a contact through which a predetermined region of the semiconductor substrate is exposed, and forming an oxide film on a surface of the first and second interlayer insulation films by performing a surface process using ozone.

The anneal process may be performed at a temperature of 700 to 900° C. in nitrogen (N₂) ambient for 30 to 60 minutes. The surface process using ozone may be performed at a temperature of 500 to 700° C. The oxide film may be formed to a thickness of 30 to 50 Å. The method may further include the step of performing a cleaning process of removing etch remnants when the contact is formed after the surface process using ozone is performed. The cleaning process may be performed using chemicals including one or more of the following: H₂SO₄, H₂O₂, NH₄OH, HF and NH₄F. The second interlayer insulation film may be formed using a tetraethoxysilane (TEOS) oxide film or a High Density Plasma (HDP) oxide film.

### BRIEF DESCRIPTION OF THE DRAWINGS

FIGS. 1a to 1c are sectional views of semiconductor devices for illustrating a method of manufacturing the semiconductor devices according to an embodiment of the present invention; and

FIGS. 2a to 2c are sectional views of semiconductor devices for illustrating a method of manufacturing the semiconductor devices according to another embodiment of the present invention.

### DETAILED DESCRIPTION OF THE INVENTION

The present invention will now be described in connection with preferred embodiments with reference to the accompanying drawings.

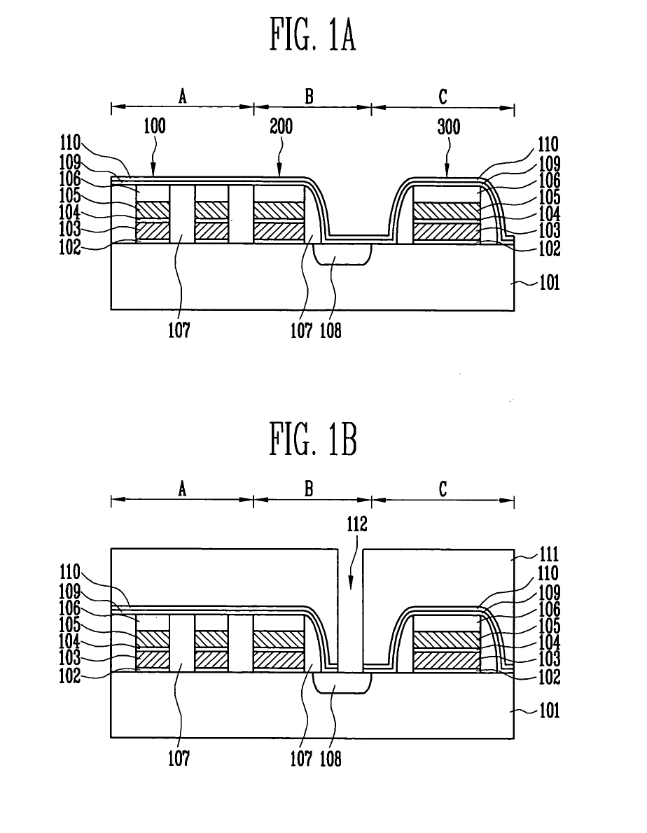

FIGS. 1a to 1c are sectional views of semiconductor devices for illustrating a method of manufacturing the semiconductor devices according to an embodiment of the present invention. FIG. 1 is a sectional view for illustrating a method of forming a drain contact of a NAND flash memory device. This method can be applied to a source contact in the same manner.

Referring to FIG. 1a, a tunnel oxide film 102, a first conduction layer 103, a dielectric film 104, a second conduction layer 105 and a hard mask film 106 are sequentially formed on a semiconductor substrate 101 in which a cell region A, a select transistor region B and a peripheral region C are partitioned by a predetermined process. Photolithography and etch processes using a predetermined mask is then performed to form a stack gate 100 in which a floating gate and a control gate are stacked in the cell region A and a gate 200 in which first and second conduction layers 103, 105 are stacked in the select transistor region B. A gate 300 in which first and second conduction layers 103, 105 are stacked is also formed in the peripheral region C.

The stack gate 100 of the cell region A, the gate 200 of the select transistor region B and the gate 300 of the peripheral region C are formed by the same process in the present embodiment, but are used differently as a memory cell or control transistors. In other words, a first voltage is applied to the control gate in the stack gate 100 of the cell region A, so that the stack gate operates as a memory cell. A second voltage is applied to the first and second conduction layers 103, 105 of the gate 200 and the gate 300, so that the gate 200 and the gate 300 operate as the control transistors. In another embodiment, the gates 200 and 310 are applied with different voltages.

An insulation film 107 is formed and then undergoes blanket etch to be provided between the gates 100 of the cell region A. Spacers are formed on sidewalls of the gates 200, 300 of the select transistor region B and the peripheral region C. An ion implant process is then performed to form a source region (not shown) and a drain region 108. A buffer oxide film 109 and a nitride film 110 for a self-aligned contact etch process are then formed on the entire structure.

Referring to FIG. 1b, an interlayer insulation film 111 is formed of O₃-TEOS on the entire structure. An anneal process is performed at a temperature of 700 to 900° C. under a nitrogen (N₂) atmosphere for 30 to 60 minutes in order to densify or harden the interlayer insulation film 111. After a photoresist film (not shown) is formed on the entire structure, a drain contact hole 112 is formed to expose the drain 108. The contact hole 112 is formed by a photolithography process.

Referring to FIG. 1c, the photoresist film (not shown) is removed using plasma generated from oxygen. A surface process using ozone is then performed to form an oxide film 113 on a surface of the interlayer insulation film 111. The surface process using ozone is performed at a temperature of 500 to 700° C., so that the oxide film 113 is formed to a thickness of 30 to 50 Å. A cleaning process is carried out to remove polymer residue remaining on the substrate after the photoresist film has been removed. The cleaning process is performed using chemicals including one or more of the following: H₂SO₄, H₂O₂, NH₄OH, HF and NH₄F. The oxide film 113 prevents the bottom of the interlayer insulation film 111, that may not have been sufficiently hardened, from being removed. As a result, a plug material may completely filled into the contact hole 112 more easily.

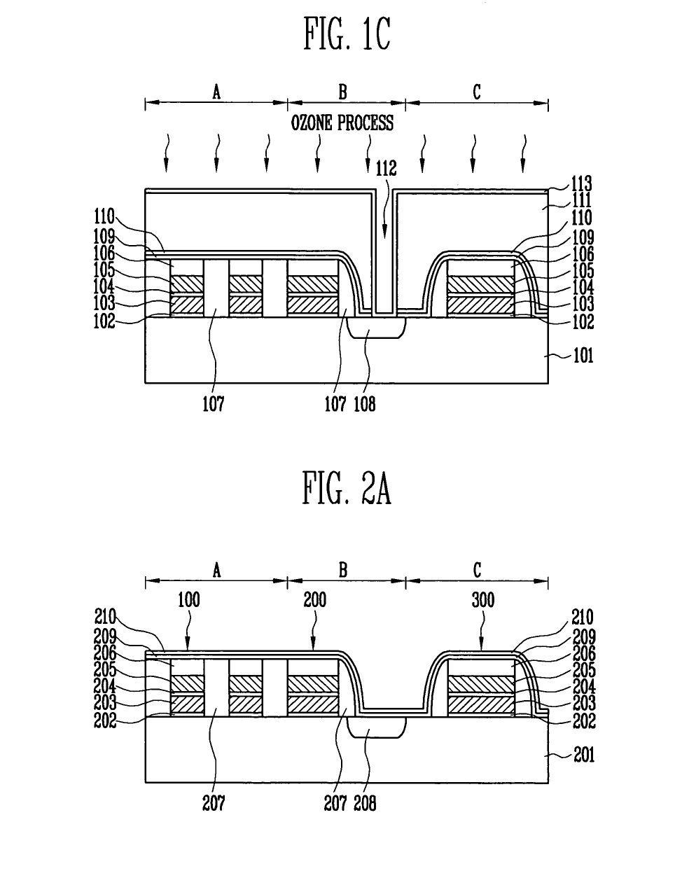

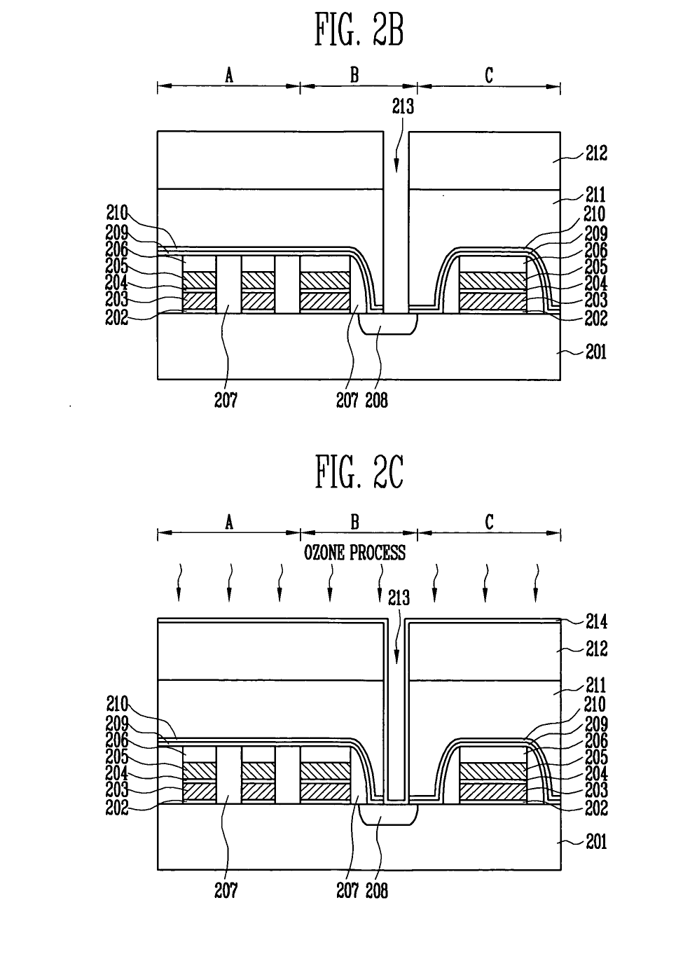

FIGS. 2a to 2c are sectional views of semiconductor devices for illustrating a method of manufacturing the semiconductor devices according to another embodiment of the present invention. FIG. 2 is a sectional view for illustrating a method of forming a drain contact of a NAND flash memory device. This method can be applied to a source contact in the same manner.

Referring to FIG. 2a, a tunnel oxide film 202, a first conduction layer 203, a dielectric film 204, a second conduction layer 205 and a hard mask film 106 are sequentially formed on a semiconductor substrate 201 in which a cell region A, a select transistor region B and a peripheral region C are partitioned by a predetermined process. Photolithography and etch processes using a predetermined mask is then performed to form-stack gates 100 in which a floating gate 203 and a control gate 205 are stacked in the cell region A. A gate 200 in which first and second conduction layers 203, 205 are stacked in the select transistor region B is formed. A gate 300 in which first and second conduction layers 203, 205 are stacked is formed in the peripheral region C.

The stack gate 100 of the cell region A, the gate 200 of the select transistor region B and the gate 300 of the peripheral region C are formed by the same process, but are used for different purposes. In other words, a first voltage is applied to the control gate in the stack gate 100, so that the stack gate operates as a memory cell to store data. A second voltage is applied to both the first and second conduction layers 203, 205 of the gate 200 to use them as part of a control transistor. Similarly, the gate 300 is used as a control transistor. A third voltage is applied to both of the layers 203, 205 of the gate 300. The second and third voltages may be different or the same.

An insulating film is provided between gates 100 of the cell region A. After spacers 207 are formed on sidewalls of the gates 200, 300, an ion implant process is performed to form a source region (not shown) and a drain region 208. A buffer oxide film 209 and a nitride film 210 for a self-aligned contact etch process are then formed on the entire structure.

Referring to FIG. 2b, a first interlayer insulation film 211 is formed of O₃-TEOS (tetraethoxysilane) on the entire structure. An anneal process is performed at a temperature of 700 to 900° C. in nitrogen (N₂) ambient for 30 to 60 minutes in order to densify the first interlayer insulation film 211. A second interlayer insulation film 212 is then formed on the first interlayer insulation film 211. The film 212 may be formed of a TEOS oxide film or a High Density Plasma (HDP) oxide film. After a photoresist film (not shown) is formed on the entire structure, a drain contact hole 213 is formed by a photolithography process to expose the drain 208.

Referring to FIG. 2c, the photoresist film (not shown) is removed using plasma generated from oxygen. A surface process using ozone is then performed to form an oxide film 214 on surfaces of the first and second interlayer insulation films 211, 212. The oxide film 214 lines or coats the contact hole 203. The surface process using ozone can be performed at a temperature of 500 to 700° C. so that the oxide film 214 is formed to a thickness of 30 to 50 Å. A cleaning process is carried out to remove polymer residue remaining on the substrate after the photoresist film has been removed. The cleaning process is performed using one or more of the following chemicals: H₂SO₄, H₂O₂, NH₄OH, HF and NH₄F. Since the first interlayer insulation film 211 can be removed faster than the second interlayer insulation film 212 during the cleaning step, the bottom of the first interlayer insulation film 211 may be removed too much. This would result in a trench or hole that has a wider lower portion, which would result in difficulty in filling the trench or hole. The oxide film 214 helps with this problem by lining the trench or hole. Also, the film 214 helps in preventing excessive removal of the lower part of the first insulation film 211 that results from the lower part not being sufficiently hardened during the annealing.

As described above, according to the present invention, since a bottom of an interlayer insulation film formed of O₃-TEOS may not have hardened sufficiently, the lower part of the trench/contact hole may be removed too much during a cleaning process. An oxide film formed by a surface process using ozone is formed or coated on the surface of the trenches to prevent excessive loss of material at the lower part of the trench. Therefore, the present invention helps in preventing voids that may result when the trench is not completely filled with a plug material.

Although the foregoing description has been made with reference to the preferred embodiments, it is to be understood that changes and modifications of the above embodiments may be made by the ordinary skilled in the art without departing from the spirit and scope of the present invention.

What is claimed is:

1. A method of manufacturing semiconductor devices, the method comprising:
forming an interlayer insulation film over a semiconductor substrate, the substrate having a first gate structure for a memory cell and a second gate structure for a control transistor, the interlayer insulation film overlying the first and second gate structures;
annealing the interlayer insulation film;
etching the interlayer insulation film to form a contact hole to expose a conductive region associated with the second gate structure; and
forming an oxide film over a surface of the interlayer insulation film and over a surface of the contact hole using ozone.

2. The method as claimed in claim 1, wherein the annealing is performed at a temperature of 700 to 900° C. in nitrogen (N₂) ambient for 30 to 60 minutes.

3. The method as claimed in claim 1, wherein the surface process using ozone is performed at a temperature of 500 to 700° C.

4. The method as claimed in claim 1, wherein the oxide film is formed to a thickness of no more than 50 Å.

5. The method as claimed in claim 1, further comprising performing a cleaning process to remove residues from the etching step, wherein the oxide film prevents the interlayer insulation film on a lower portion of the contact hole from being removed excessively during the cleaning process

6. The method of claim 1, wherein the interlayer insulation film is formed using O₃-TEOS, wherein the conductive region is a drain or source region of the second gate structure.

7. A method of manufacturing semiconductor devices, the method comprising:
forming a first interlayer insulation film using O₃-TEOS over a semiconductor substrate having first and second gate structures, the first gate structure provided in a memory cell region and being configured to store data, the second gate structure that is provided in a non-memory cell region and being configured to use as a control transistor;
annealing the first interlayer insulation film to harden the first interlayer insulation film;
forming a second interlayer insulation film over the first interlayer insulation film;
etching the first and second interlayer insulation films to form a contact hole to expose a conductive region associated with the second gate structure; and
forming an oxide film over a surface of the first and second interlayer insulation films using ozone.

8. The method as claimed in claim 7, wherein the annealing is performed at a temperature of 700 to 900° C. in nitrogen (N₂) ambient for 30 to 60 minutes, wherein the annealing is performed after the forming the second interlayer insulation film.

9. The method as claimed in claim 7, wherein the surface process using ozone is performed at a temperature of 500 to 700° C., wherein the annealing is performed prior to form the second interlayer insulation film.

10. The method as claimed in claim 7, wherein the oxide film is formed to a thickness of no more than 50 Å.

11. The method as claimed in claim 7, further comprising performing a cleaning process to remove residues remaining from the etching step.

12. The method as claimed in claim 11, wherein the cleaning process is performed using chemicals one or more of the following: H₂SO₄, H₂O₂, NH₄OH, HF and NH₄F.

13. The method as claimed in claim 7, wherein the second interlayer insulation film is formed using a tetraethoxysilane (TEOS) oxide film or a High Density Plasma (HDP) oxide film.
